(19) United States
(12) Patent Application Publication
(10) Pub. No.: US 2026/0331860 A1
(43) Pub. Date: Oct. 22, 2026

(54) EMBEDDED ADAPTIVE CONTROL SIGNAL INTERLOCK ALGORITHM FOR LASER SYSTEMS

(71) Applicant: Lumentum Operations LLC, San Jose, CA (US)

(72) Inventor: Amir GAFNI, San Jose, CA (US)

(21) Appl. No.: 19/241,807

(22) Filed: Jun. 18, 2025

Related U.S. Application Data
(60) Provisional application No. 63/791,297, filed on Apr. 18, 2025.

(51) Int. Cl. H01S 3/13

(52) U.S. Cl. CPC H01S 3/1305; H01S 3/1303

(57) ABSTRACT

In some implementations, a laser system may measure a first control voltage at a first time, a first photodetector voltage at a second time that is after the first time, and a second control voltage at a third time that is after the second time. The laser system may determine that the laser system is in a steady-state based on comparing the first control voltage and the second control voltage to one or more thresholds. The laser system may compare the first photodetector voltage to a voltage range based on determining that the laser system is in the steady-state. The laser system may determine whether to perform a laser shutdown procedure based on comparing the first photodetector voltage to the voltage range.

### CROSS-REFERENCE TO RELATED APPLICATION

This Patent Application claims priority to U.S. Patent Application No. 63/791,297, filed on Apr. 18, 2025, and entitled “EMBEDDED ADAPTIVE CONTROL SIGNAL INTERLOCK ALGORITHM FOR LASER SYSTEMS.” The disclosure of the prior Application is considered part of and is incorporated by reference into this Patent Application.

### TECHNICAL FIELD

The present disclosure relates generally to laser systems and to adaptive control signal interlock algorithms.

### BACKGROUND

A laser interlock system is a safety mechanism designed to prevent accidental exposure to hazardous laser radiation by automatically disabling the laser when the laser is not operating within defined safety parameters. Such interlock systems can monitor a single operational input (such as door status, beam path integrity, or enclosure integrity) to determine whether the laser should remain armed or be shut down. However, laser interlock systems relying on single-input monitoring necessitate manual calibration of arming and disarming thresholds to ensure proper and timely response to unsafe conditions. This manual calibration process can be time-consuming and imprecise, leading to inefficiencies in system setup and maintenance, and potentially introducing delays in response time if thresholds are not optimally configured. As a result, reliance on single-input mechanisms with manually set thresholds may compromise both the efficiency and effectiveness of laser safety protocols.

### SUMMARY

Some aspects described herein relate to a method performed by a laser system. The method may include measuring a first control voltage at a first time, a first photodetector voltage at a second time that is after the first time, and a second control voltage at a third time that is after the second time; determining that the laser system is in a steady-state based on comparing the first control voltage and the second control voltage to one or more thresholds; comparing the first photodetector voltage to a voltage range based on determining that the laser system is in the steady-state; and determining whether to perform a laser shutdown procedure based on comparing the first photodetector voltage to the voltage range.

Some aspects described herein relate to a laser system. The laser system may include a one or more memories and one or more processors, coupled to the one or more memories. The one or more processors may be configured to cause the laser system to measure a first control voltage at a first time, a first photodetector voltage at a second time that is after the first time, and a second control voltage at a third time that is after the second time; determine that the laser system is in a steady-state based on comparing the first control voltage and the second control voltage to one or more thresholds; compare the first photodetector voltage to a voltage range based on determining that the laser system is in the steady-state; and determine whether to perform a laser shutdown procedure based on comparing the first photodetector voltage to the voltage range.

Some aspects described herein relate to a laser system. The laser system may include a laser; a function generator configured to generate a control signal; a control interface configured to provide the control signal as input to the laser; a photodetector configured to measure an output intensity from the laser; a relay configured to disconnect the laser from a power source; one or more memories storing one or more instructions of an adaptive control signal interlock algorithm (ACSIA); and one or more processors, coupled to the one or more memories, wherein the one or more processors are configured to obtain, from the function generator, a first control voltage at a first time and a second control voltage at a third time; obtain, from the photodetector, a first photodetector voltage at a second time, wherein the second time is after the first time and before the third time; determine that the laser is in a steady-state based on comparing the first control voltage and the second control voltage to one or more thresholds; compare the first photodetector voltage to a voltage range based on determining that the laser system is in the steady-state; and determine whether to trigger the relay to perform a laser shutdown procedure based on comparing the first photodetector voltage to the voltage range.

### BRIEF DESCRIPTION OF THE DRAWINGS

FIG. 1 shows a diagram illustrating an example of a laser interlock system, that includes one or more components.

FIG. 2 shows an example of a process implemented by a laser interlock system according to one or more implementations.

FIGS. 3A and 3B shows diagrams that illustrate examples of a voltage plot where the laser interlock system identifies whether an interlock should be in an armed or disarmed state.

FIG. 4 shows a photodetector voltage sampling plot according to a laser system operating according to the adaptive control signal interlock algorithm (ACSIA) versus a cycle-wide averaging procedure.

FIGS. 5A through 5D shows an example voltage sampling plot over different points in time according to one or more implementations.

FIG. 6 is a flowchart of an example process associated with embedded ACSIA for laser systems.

### DETAILED DESCRIPTION

The following detailed description of example implementations refers to the accompanying drawings. The same reference numbers in different drawings may identify the same or similar elements.

A laser interlock system is a safety mechanism designed to prevent unauthorized or unsafe operation of laser equipment. For instance, a laser interlock system ensures that an associated laser can only be activated under safe conditions, thereby protecting users and preventing accidental exposure to harmful laser radiation. A laser interlock system typically involves a series of checks and controls that are to be satisfied before the laser can be powered on and/or remain operational. These checks can include door interlocks, emergency stop buttons, and/or environmental sensors, among other safety measures.

Some laser interlock systems make use of single-input monitoring mechanisms, such as photodetector (PD) feedback or fixed-threshold voltage control. In a PD feedback system, a PD is positioned to monitor the laser output. The PD continually measures the intensity of the laser beam and provides real-time feedback to the interlock system. If the detected laser intensity exceeds a predefined safe threshold, the interlock system may automatically shut down the laser to prevent potential harm. Additionally, fixed-threshold voltage control may involve monitoring a specific voltage level that corresponds to the safe operation of the laser. This voltage can be derived from various sensors or control circuits within the laser system. If the monitored voltage deviates from the predefined safe range, the interlock system can trigger a shutdown of the laser.

However, laser interlock systems that rely on single-input monitoring mechanisms may require manual calibration of interlock arming and/or disarming thresholds, leading to inefficiencies and potential delays in response time. Additionally, various types of interlock systems do not provide automated adaptation to varying modulation conditions, particularly for slow-modulated laser signals (e.g., lasers with a modulation cycle greater than 1 second (s)). Additionally, determining a state of a control signal (rising, falling, steady-state, or off) may be used to interpret PD measurements and influence interlock decisions. However, single-input monitoring mechanisms may misinterpret transient variations due to fixed-threshold voltage control, leading to false interlock activations. Additionally, laser power exhibits an inherent latency when responding to control voltage changes due to driver circuit delays, thermal effects, and diode switching time. Accordingly, evaluating the PD signal too early can result in inaccurate measurements, causing false interlock triggers. Additionally, changes in laser power (caused by modulation transitions, overshoot/undershoot effects, and/or power driver delays) can create transient errors in PD readings. These fluctuations may lead to incorrect interlock decisions, either falsely triggering shutdowns or failing to detect unsafe conditions. Additionally, a drop in PD voltage may indicate either a fiber break (e.g., an actual fault) or a modulation-induced power reduction (e.g., an intentional event). However, single-input monitoring mechanisms struggle to distinguish between actual faults and intentional events, leading to false shutdowns and/or unsafe conditions.

Some implementations described herein provide a laser interlock system that integrates adaptive threshold calculation with real-time steady-state verification using an external control voltage signal. For example, the laser interlock system may operate in accordance with an adaptive control signal interlock algorithm (ACSIA). Conversely to laser interlock systems that use single-input monitoring mechanisms, the ACSIA continually monitors the laser control signal to determine whether the interlock can be safely armed or disarmed. The ACSIA may utilize a three-measurement sequence (that leverages dual-input monitoring with adaptive thresholds) to directly verify control signal stability before allowing PD measurements to be processed. For instance, the ACSIA may continually track the control voltage alongside PD voltage to determine if a power drop is expected or is an anomaly. If the control signal remains stable while PD voltage drops unexpectedly, the laser interlock system may detect a possible fiber break and trigger an interlock. However, if the control voltage itself is modulating, ACSIA recognizes the event as intentional and prevents laser shutdowns. Accordingly, the three-measurement sequence ensures that PD readings are only taken when the laser is stabilized at a power level that satisfies a configured power threshold, reducing false alarms and enhancing system reliability.

Unlike other laser interlocks that rely on filtering or averaging techniques (which introduce latency), the ACSIA-based interlock focuses on the steady-state portions of the laser output, which enables a faster response time, ensuring that anomalies in a laser output are detected and acted upon. Accordingly, the ACSIA may reduce processing delays by measuring only during steady-state portions of the laser output, which enhances system reliability and minimizes the risk of laser damage. Furthermore, the high-speed response of ACSIA contributes to improved operator safety, reducing the risk of hazardous exposure due to delayed interlock activation.

Additionally, or alternatively, the ACSIA may implement a configurable wait time to ensure that the laser output has fully stabilized before the PD measurement is taken. This wait time can be adjusted based on laser characteristics, preventing false alarms while maintaining fast response times for interlock activation. Additionally, or alternatively, the ACSIA can verify that the control voltage is stable before processing PD measurements. By using three sequential control voltage samples, ACSIA ensures that only steady-state conditions are considered, filtering out transient effects and improving interlock reliability.

By dynamically assessing steady-state conditions before processing PD measurements, the ACSIA ensures reliable protection across various modulation scenarios, enabling interlock functionality for modulated laser systems. For instance, the ACSIA may be effective for applications of laser systems involving slow modulation signals (e.g., greater than 1 second) with varying duty cycles. Other signal processing methods (such as cycle-wide averaging) may be unable to adapt to dynamic control signal variations, whereas ACSIA ensures precise thresholding and interlock protection under various modulation conditions. Additionally, the dynamic control resulting from ACSIA enables laser interlocking systems to prevent fiber-related faults that could cause delayed interlock responses. Additionally, the ACSIA enables protection for slow modulation signals (e.g., less than 1 Hertz (Hz)) while maintaining response times comparable to a continuous wave (CW)-mode (e.g., less than 1 millisecond (ms)). Additionally, the sequential measurements of control voltages before and after the PD voltage measurement provide a reliable approach to determining whether the control signal is rising, falling, at steady-state, or off. This ensures that PD voltage measurements are taken when the laser has reached an intended maximum power, thereby preventing false interlock alarms. Additionally, the ACSIA may continually take control voltage measurements before processing PD data to ensure that interlock decisions are based on stable and accurate inputs.

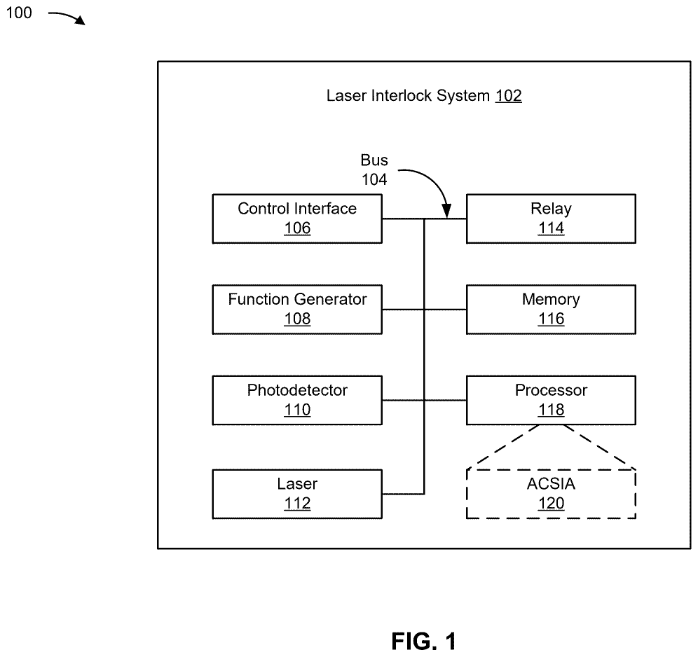

FIG. 1 shows a diagram illustrating an example 100 of a laser interlock system 102, that includes one or more components. As shown in FIG. 1, the laser interlock system 102 may include a bus 104, a control interface 106, a function generator 108, a photodetector 110, a laser 112, a relay 114, a memory 116, and/or a processor 118 that enables the laser interlock system to perform one or more operations according to an ACSIA 120. In some examples, the laser interlock system 102 may be referred to elsewhere herein as a “laser system.”

The bus 104 may include one or more components that enable wired and/or wireless communication among the components of the laser interlock system 102. The bus 104 may couple together two or more components of FIG. 1, such as via operative coupling, communicative coupling, electronic coupling, and/or electric coupling. For example, the bus 104 may include an electrical connection (e.g., a wire, a trace, and/or a lead) and/or a wireless bus.

The control interface 106 of the laser interlock system 102 is configured as a voltage input module (e.g., 0-10 V, or some other range of voltages) that supplies a control voltage to modulate the output power of the laser 112. This control interface 106 receives an analog voltage signal within the voltage range, which directly determines the operational power level of the laser 112. Specifically, the supplied control voltage is proportional to the output power of the laser 112, such that an increase or decrease in the control voltage results in a corresponding change in the output of the laser 112. For example, if the maximum output power of the laser 112 is defined as 100 megawatts, then a control voltage of 1.5 V (between the range 0-10 V) applied to the control interface 106 may set the laser 112 to an output of 15 megawatts. This proportional relationship allows for precise and flexible adjustment of laser power, providing both operational efficiency and safety within the laser interlock system 102.

The function generator 108 of the laser interlock system 102 is designed to generate and distribute a control signal that governs the modulation of the laser 112. Equipped with an optional Bayonet Neill-Concelman (BNC) splitter, the function generator 108 can concurrently route the generated control signal to both the laser 112 and the processor 118. This configuration enables the function generator 108 to serve as a central hub for synchronizing laser operation and system monitoring or data acquisition functions. By providing the control signal in parallel to these critical components, the function generator 108 ensures that both the laser 112 receives the appropriate modulation input for power control and the processor 118 remains updated with real-time operational parameters. The use of a BNC splitter further enhances connectivity and signal integrity, supporting reliable and coordinated operation within the laser interlock system 102.

The photodetector 110 of the laser interlock system 102 is may be configured to monitor the total output of the laser 112 and providing real-time feedback on the performance of the laser 112. Specifically, the photodetector 110 may be positioned to receive a portion of the emitted laser light (e.g., via an optical pick-off or similar arrangement) and measures the intensity of the laser output. This measured optical signal may be converted by the photodetector 110 into a proportional voltage, which can be processed and analyzed by other components of the laser interlock system 102, such as the processor 118. By continuously converting the total laser output into a voltage, the photodetector 110 enables monitoring and control of laser performance, facilitating safety interlock functions and ensuring that the laser 112 operates within desired parameters. In some implementations, the photodetector 110 may be a photodiode.

The laser 112 of the laser interlock system 102 is designed to accommodate a wide range of laser types and architectures that utilize control signal modulation for power and operational management. This flexibility allows the laser interlock system 102 to interface with and/or control various laser technologies, including but not limited to fiber lasers, fiber amplifiers, semiconductor (diode) lasers, and solid-state lasers (such as a neodymium-doped yttrium aluminum garnet (Nd: YAG) solid state laser). Additionally, the laser 112 may be implemented as a carbon dioxide (CO₂) laser, which may be used in industrial and/or medical applications, or as an ultrafast pulsed laser for research and/or manufacturing processes. The laser interlock system 102 is also compatible with quality factor (Q)-switched laser sources and other modulated laser sources, enabling rapid switching and modulation of the laser output. By supporting such a diverse array of laser types, the laser 112 ensures the laser interlock system 102 can be integrated into numerous applications and environments, providing robust and adaptable laser control based on the specific requirements of the installation.

The relay 114 of the laser interlock system 102 may be implemented as a solid-state relay (SSR) (or another type of relay) that plays a role in maintaining operational safety. The relay 114 is responsible for disconnecting the laser 112 from a power source and/or control circuitry based on the detection of unsafe operating conditions (such as excessive output, system faults, and/or breaches in safety protocols). Conversely to electromechanical relays, a solid-state relay offers faster response times and increased reliability based on a reduction in a number moving parts, enabling a faster response in interruption of laser operation when initiated. The relay 114 may receive and/or obtain signals from the processor 118 and/or other monitoring components, and when an unsafe condition is detected, may isolate the laser 112 to prevent potential hazards to users, equipment, and/or the environment. The integration of the relay 114 thus enhances the overall safety and dependability of the laser interlock system 102.

The memory 116 may include volatile and/or nonvolatile memory. For example, the memory 116 may include random access memory (RAM), read only memory (ROM), a hard disk drive, and/or another type of memory (e.g., a flash memory, a magnetic memory, and/or an optical memory). The memory 116 may include internal memory (e.g., RAM, ROM, or a hard disk drive) and/or removable memory (e.g., removable via a universal serial bus connection). The memory 116 may be a non-transitory computer-readable medium. The memory 116 may store information, one or more instructions, and/or software (e.g., one or more software applications) related to the operation of the laser interlock system 102. For instance, the memory 116 may store the ACSIA 120, a portion of the ACSIA 120, and/or one or more instructions that (when performed by the processor 118) enable one or more operations of the ACSIA 120. In some aspects, the memory 116 may include one or more memories that are coupled (e.g., communicatively coupled) to one or more processors (e.g., processor 118), such as via the bus 104. Communicative coupling between a processor 118 and a memory 116 may enable the processor 118 to read and/or process information stored in the memory 116 and/or to store information in the memory 116.

The processor 118 may include a central processing unit, a graphics processing unit, a microprocessor, a controller, a microcontroller, a digital signal processor, a field-programmable gate array, an application-specific integrated circuit, and/or another type of processing component. The processor 118 may be implemented in hardware, firmware, or a combination of hardware and software. In some aspects, the processor 118 may include one or more processors capable of being programmed to perform one or more operations or processes (such as the ACSIA 120) described elsewhere herein.

In some aspects, the laser interlock system 102 may include means for measuring a first control voltage at a first time, a first photodetector voltage at a second time that is after the first time, and a second control voltage at a third time that is after the second time; and/or means for determining that the laser system is in a steady-state based on comparing the first control voltage and the second control voltage to one or more thresholds; and/or means for comparing the first photodetector voltage to a voltage range based on determining that the laser system is in the steady-state; and/or determining whether to perform a laser shutdown procedure based on comparing the first photodetector voltage to the voltage range. In some aspects, the means for laser interlock system 102 to perform processes and/or operations described herein may include one or more components of laser interlock system 102 described in connection with FIG. 1, such as the bus 104, the control interface 106, the function generator 108, the photodetector 110, the laser 112, the relay 114, the memory 116, and/or the processor 118.

The number and arrangement of components shown in FIG. 1 are provided as an example. The laser interlock system 102 may include additional components, fewer components, different components, or differently arranged components than those shown in FIG. 1. Additionally, or alternatively, a set of components (e.g., one or more components) of the laser interlock system 102 may perform one or more functions described as being performed by another set of components of the laser interlock system 102.

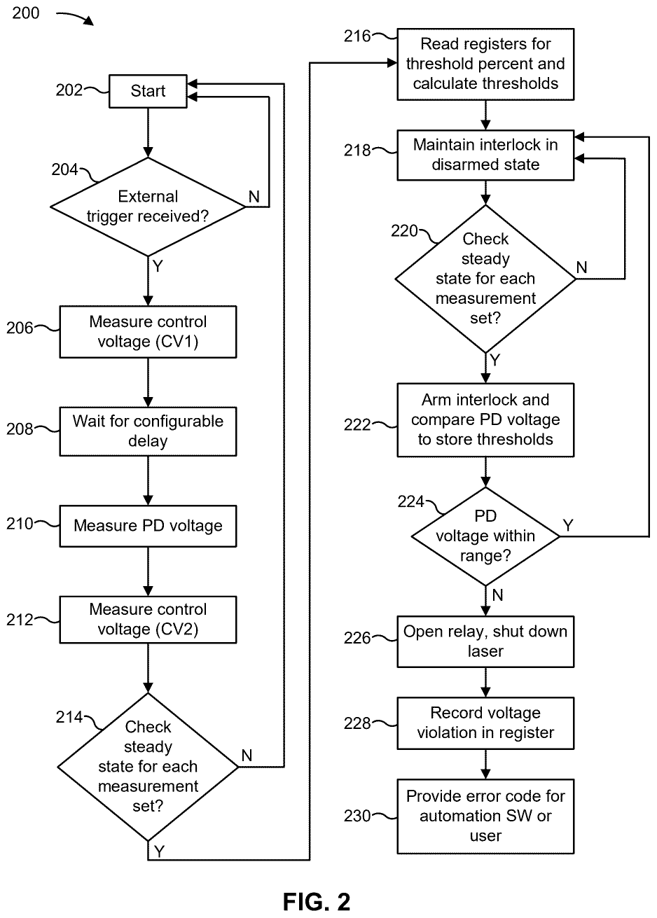

FIG. 2 shows an example 200 of a process implemented by a laser interlock system 102 according to one or more implementations. For example, the laser interlock system 102 may automatically adapt to varying control signals to ensure operational safety and efficiency. The laser interlock system 102 may integrate real-time PD feedback and control voltage monitoring to dynamically determine safe operating conditions. In some examples, the operations of example 200 may be part of or correspond to operations of the ACSIA 120. In some implementations, the signal-driven approach of ACSIA 120 allows for integration into diverse platforms and supports both standalone safety interlocks and embedded laser control systems. In some examples, one or more components of the laser interlock system 102 may perform one or more aspects and/or operations of process of example 200 (e.g., the bus 104, the control interface 106, the function generator 108, the photodetector 110, the laser 112, the relay 114, the memory 116, and/or the processor 118).

In some implementations, the laser interlock system 102 may include an automatic threshold calculation mode. For example, when triggered externally (by an operator or automated test system) the laser interlock system 102 performs a threshold calculation to establish one or more thresholds (e.g., to determine an operating voltage range for the photodetector 110). The ACSIA 120 may verify that the control voltage is stable before proceeding with the computation. After the one or more thresholds are established, the one or more thresholds may remain fixed until another external request initiates recalibration.

In some implementations, the laser interlock system 102 may include a real-time monitoring and interlock processing mode. For example, after a threshold calculation, the laser interlock system 102 enters a continuous loop to monitor control voltage and laser 112 status. During a given loop, the laser interlock system 102 takes three sequential measurements to determine whether the control signal is rising, falling, at steady-state, or off. If steady-state conditions are met, a voltage measured by the photodetector 110 during the given loop (e.g., referred to herein as the “PD voltage”) is compared against the voltage range that was calculated during the automatic threshold calculation mode. If the PD voltage remains within the defined voltage range, the interlock of the laser interlock system 102 may disarm. If the PD voltage falls outside one of the voltage range, the laser interlock system 102 logs the event, provides an error code, and/or opens a relay 114 (e.g., the SSR) to shut down the laser 112 of the laser interlock system 102.

As shown in FIG. 2, example 200 is a process that corresponds to the laser interlock system 102 operating in accordance with the ACSIA 120 to perform one or more operations. The one or more operations performed by the laser interlock system 102 correspond to the one or more reference numbers of example 200. Alternative examples of the following may be implemented, where some operations are performed in a different order than described, or not described at all. In some cases, one or more operations may include additional features not mentioned below, or further operations may be added. In addition, while the description below describes the laser interlock system 102 performing the one or more operations, any component that is part of or associated with the laser interlock system 102 may perform the one or more operations.

As shown by reference number 202, the laser interlock system 102 may idle at the start until an external trigger is received (e.g., by an operator or automated test system). For example, the operator may trigger the laser interlock system to perform enter the automatic threshold calculation mode to determine the voltage range for output volage of the photodetector 110.

As shown by reference number 204, the laser interlock system 102 may determine whether an external trigger is received. If an external trigger is not received, then the laser interlock system 102 may revert to the start.

As shown by reference number 206, if an external trigger is received, then the laser interlock system 102 may measure a first control voltage (CV1). For example, the processor 118 of the laser interlock system 102 may read CV1, which may serve as an initial control voltage measurement to establish a baseline voltage.

As shown by reference number 208, after measuring CV1, the laser interlock system 102 may wait for a duration of time based on a configurable delay. For instance, the configurable delay accounts for photodetector 110 latency and transient effects before evaluating PD signals. The latency of the photodetector 110 relative to the output of the laser 112 may be based on one or more electronic processes that introduce delays. For example, the photons emitted from the laser 112 travel to the lens of the photodetector 110. Additionally, once the photons strike the active surface of the photodetector 110, the photodetector 110 converts the light into an electrical signal, a process that involves carrier generation, separation, and transport within the material of the active surface. This photoelectric conversion induces latency and introduces a finite response time, that may be referred to herein as the “rise time” of the photodetector 110. Additionally, or alternatively, the resulting electrical signal may pass through amplification and signal processing circuitry (e.g., the bus 104 and/or the processor 118), which further adds to the delay. Accordingly, the duration of the configured delay between measuring CV1 and measuring the PD voltage may account for one or more of the electronic processes described herein.

As shown by reference number 210, after waiting the configurable delay, the laser interlock system 102 may measure a voltage of the photodetector 110. For instance, the PD voltage may be measured to assess the output of the laser 112.

As shown by reference number 212, after measuring the PD voltage, the laser interlock system 102 may measure a second control voltage (CV2). Measuring the value of CV2 enable the laser interlock system 102 to determine whether the control voltage has remained stable between the CV1 measurement and the CV2 measurement.

As shown by reference number 214, the laser interlock system 102 may check whether a steady-state was measured for the set of voltage measurements (e.g., CV1, CV2, and the PD voltage). The steady-state check may also be referred to herein as a “stability verification.” As part of the stability verification, the values of CV1 and CV2 may be compared to multiple configurable thresholds. For instance, a threshold “Noise_Threshold” may be a configurable value that compensates for electrical noise and transient fluctuations. Additionally, the threshold “Configurable_Max_Control_Signal” may be a configurable value that defines the minimum control voltage for confirming a steady-state. The value of Noise_Threshold and/or Configurable_Max_Control_Signal can be manually set or automatically detected by the ACSIA 120 during calibration. If |CV1-CV2|≥Noise_Threshold or CV1≤Configurable_Max_Control_Signal, then the laser interlock system 102 determines that the set of voltage measurements are not in a steady-state and the laser interlock system 102 reverts to the start (e.g., reference number 202) until another external trigger is received.

If |CV1-CV2|<Noise_Threshold and CV1>Configurable_Max_Control_Signal, then as shown by reference number 216, the laser interlock system 102 may perform threshold calculations that correspond to the PD voltage value. For example, the laser interlock system 102 may read one or more registers of the memory 116 for stored threshold percentage values. Accordingly, the PD voltage may be multiplied by a first percentage threshold stored at the registers to determine a lower voltage safety bound for the PD voltage (e.g., low safety limit or lower bound). Additionally, the PD voltage may be multiplied by a second percentage threshold stored at the registers to determine an upper voltage safety bound for the PD voltage (e.g., high safety limit or upper bound). The first percentage threshold and the second percentage threshold may be configured based on one or more characteristics of the laser 112 (such as an allowed percentage change tolerance in the laser 112 intensity output during a steady-state of the laser 112). For instance, in one example, the first percentage threshold may be 90% and the second percentage threshold may be 105%, among other examples. In some examples, the upper voltage safety bound and the lower voltage safety bound may be stored to one or more registers of the memory 116. In some examples, the values of the upper voltage safety bound and the lower voltage safety bound may be updated, if a user provides an external trigger for the laser interlock system 102 to enter the automatic threshold calculation mode and measure an updated value of the steady-state PD voltage.

As shown by reference number 218, after setting the voltage range for the PD voltage, the interlock mechanism of the laser interlock system 102 is initially maintained in a disarmed state.

As shown by reference number 220 (similar to reference number 214), the laser interlock system 102 may check whether a steady-state was measured for the set of voltage measurements (e.g., CV1, CV2, and the PD voltage). For example, the laser interlock system 102 may take updated measurements of CV1, CV2, and/or the PD voltage and determine whether the set of voltage measurements have remained in a steady-state (e.g., compare updated CV1 and CV2 values to the threshold Noise_Threshold and Configurable_Max_Control_Signal, similar to reference number 214). If the updated measurements for CV1 and CV2 indicate the updated set of voltage measurements are not in a steady-state, then the laser interlock system 102 may maintain the interlock in the disarmed state and continuously measure values of CV1, CV2, and/or the PD voltage until the laser interlock system 102 determines that the laser 112 output is in the steady-state. In some examples, the rate at which CV1, CV2, and the PD voltage are taken during continuous measurement may be based on the hardware and/or software capabilities of one or more components of the laser interlock system 102.

If the updated measurements for CV1 and CV2 indicate that the updated set of voltage measurements are in a steady-state, then as shown by reference number 222, the laser interlock system 102 may arm the interlock mechanism and compare the updated PD voltage to the lower voltage safety bound and the upper voltage safety bound.

As shown by reference number 224, the laser interlock system 102 determines the value of the updated PD voltage relative to the upper and lower voltage safety bounds. If the updated PD voltage is within the lower voltage safety bound and the upper voltage safety bound, then then the laser interlock system 102 may disarm the interlock and proceed to continuously measure values of CV1, CV2, and/or the PD voltage.

If the updated PD voltage is outside of the lower voltage safety bound and the upper voltage safety bound, then as shown by reference number 226, the laser interlock system 102 may trigger the relay 114 to shut down the laser 112 of the laser interlock system 102. For example, the relay 114 may shut down the laser 112 by interrupting an electrical power supply to the laser 112 when the control signal is deactivated. When the processor 118 (or another component) of the laser interlock system 102 sends a signal to turn off the relay 114, the relay 114 opens an internal switch, cutting off power and causing the laser 112 to shut down. This method provides a fast, reliable, and electrically isolated procedure of controlling the laser 112.

As shown by reference number 228, after shutting down the laser 112, the laser interlock system 102 may record (e.g., write) a voltage violation in a register of the memory 116.

As shown by reference number 230, the laser interlock system 102 may provide and/or output an error code that indicates that the laser 112 was shut down. In some examples, the error code may indicate the reason why the laser 112 was shut down. For instance, the error code may indicate that the PD voltage was measured above the upper voltage safety bound, indicate that the PD voltage was measured below the upper voltage safety bound, indicate that the PD voltage was measured outside of the voltage range established by the upper and lower voltage safety bounds, indicate a value of the upper voltage safety bound, indicate a value of the lower voltage safety bound, and/or indicate a value of the measured PD voltage that resulted in the laser 112 being shut down. In some implementations, the laser interlock system 102 may send the error code to automation software configured at the laser interlock system 102 and/or may send the error code to display output for a user of the laser interlock system 102.

In accordance with the techniques of example 200, the laser interlock system 102 may leverage the ACSIA 120 to ensure that the PD voltage of the laser 112 remains within an established voltage range. If the PD voltage remains within the calculated limits, then the laser 112 may continue operating. If the PD voltage falls outside the limits, the interlock activates, triggering the SSR to shut down the laser 112.

As indicated above, FIG. 2 is provided as an example. Other examples may differ from what is shown in and described with regard to FIG. 2.

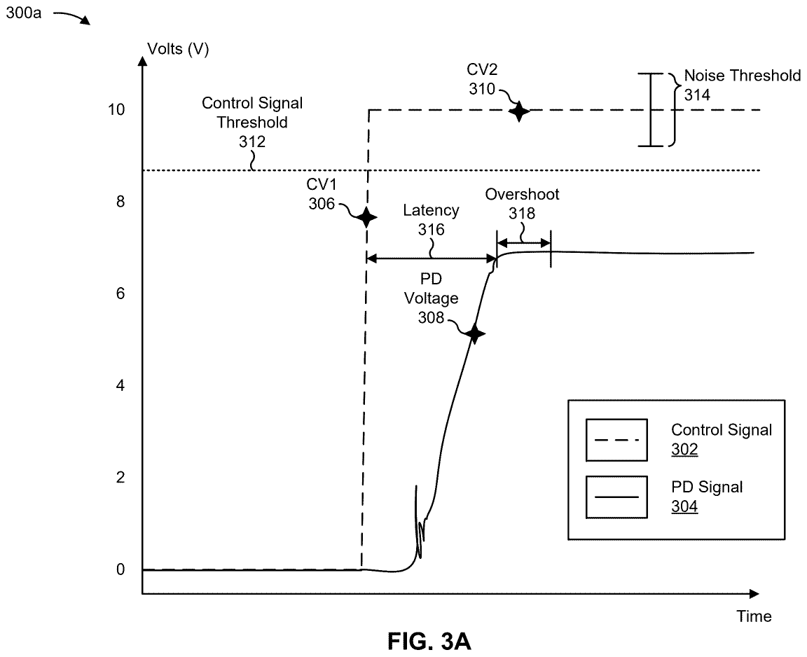

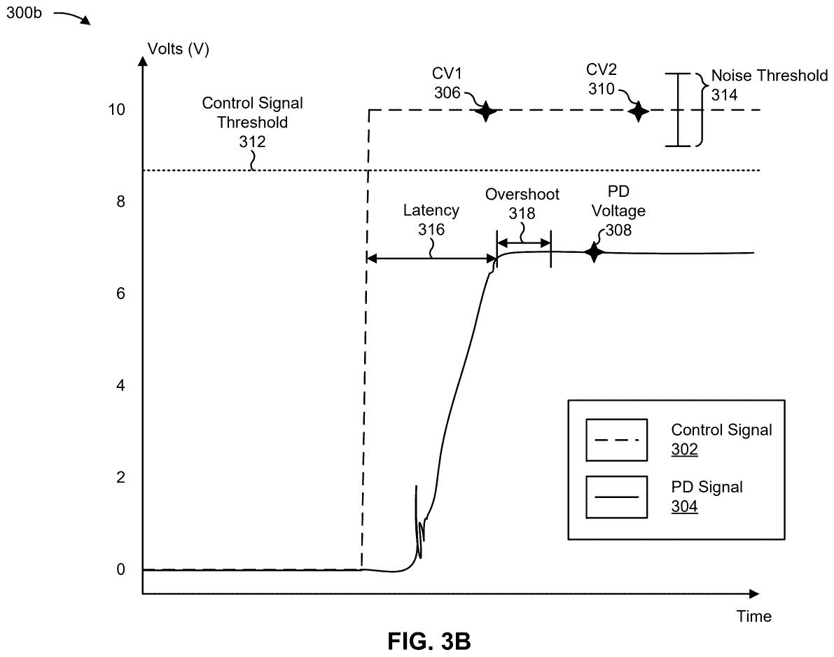

FIGS. 3A and 3B shows diagrams that illustrate examples 300a and 300b of a voltage plot where the laser interlock system 102 identifies whether an interlock should be in an armed or disarmed state. As shown in FIGS. 3A and 3B, the voltage plot includes a plot of a control signal 302 (e.g., from the control interface 106) and a PD signal 304 (e.g., measured by the photodetector 110). Additionally, the laser interlock system 102 may use one or more included components to measure a CV1 306, a PD voltage 308, and a CV2 310, which may be respective examples of measurements CV1, PD voltage, and CV2 provided herein. Additionally, the laser interlock system 102 may determine whether the laser 112 in in a steady-state by comparing the values of CV1 306 and/or CV2 310 to a control signal threshold 312 (e.g., Configurable_Max_Control_Signal) and a noise threshold 314 (e.g., Noise_Threshold).

With reference to FIG. 3A, the laser interlock system 102 identifies an interlock disarmed state according to one or more implementations. The laser interlock system 102 may utilize the ACSIA 120 to identify the interlock disarmed state. The laser interlock system 102 measures the control signal 302 at two points. For example, the initial control voltage value of CV1 306 is measured at a first time that is before measurement of the PD voltage 308 value and the second control voltage value of CV2 310 is measured at a second time that is after measurement of the PD voltage 308 value.

Additionally, as shown in FIG. 3A, (due to transient variations, latency, and/or noise) the PD voltage 308 is measured at a time such that the voltage values of CV1 306 and CV2 310 are not sufficiently close to each other, which prevents the ACSIA 120 from proceeding with threshold calculation and/or PD voltage monitoring. For example, to proceed with threshold calculation and/or PD voltage monitoring, the ACSIA 120 identifies whether both the condition of |CV1 306-CV2 310|<noise threshold 314 and the condition of CV1 306>control signal threshold 312 are met. Because (with reference to FIG. 3A) both conditions are not met, the ACSIA 120 does not process the PD voltage 308 measurement and the interlock mechanism remains disarmed.

With reference to FIG. 3B, the laser interlock system 102 identifies an interlock armed state according to one or more implementations. The laser interlock system 102 may utilize the ACSIA 120 to identify the interlock armed state. The laser interlock system 102 measures the control signal 302 at two points. For example, the initial control voltage value of CV1 306 is measured at a first time that is before measurement of the PD voltage 308 value, and the second control voltage value of CV2 310 is measured at a second time that is after measurement of the PD voltage 308 value.

As shown in FIG. 3B, both the condition of |CV1 306-CV2 310|<noise threshold 314 and the condition of CV1 306>control signal threshold 312 are met. Accordingly, the ACSIA 120 identifies that the control voltage measurements satisfy the condition of stability (e.g., in a steady-state). Based on the control voltage measurements satisfying the condition of stability, the laser interlock system 102 may use the ACSIA 120 to confirm whether the PD voltage 308 measurement falls between that control voltage values (CV1 306 and CV2 310) in time. Accordingly, the laser interlock system 102 may use the ACSIA 120 to calculate the upper voltage safety bound and the lower voltage safety bound for the PD voltage 308 (e.g., high and low PD thresholds), arm the interlock mechanism, and/or process or compare the PD voltage 308 measurement against the upper and lower voltage safety bounds. Comparing the voltage value to the upper and lower voltage safety bounds ensures that the laser 112 remains protected (e.g., against fiber breaks or unexpected modulation fluctuations).

Additionally, the laser interlock system 102 may use the ACSIA 120 to account for overshoot 318 (or undershoot) effects and/or latency 316 associated with measuring the PD voltage 308, ensuring accurate threshold setting. The ACSIA 120 mitigates latency, overshoot, and/or undershoot effects through one or more of a configurable delay and a steady-state verification via control voltage sampling. With reference to the configurable delay, after an initial control voltage is measured (e.g., CV1 306), a delay is introduced to allow the laser output to settle before sampling the photodetector 110 and compensate for the rise time of the active surface of photodetector 110. This configurable delay, therefore, compensates for rise-time delays and system-specific latency. With reference to the steady-state verification, the ACSIA 120 ensures that two consecutive control voltage measurements (CV1 306 and CV2 310) are both stable and above a configurable threshold to ensure that the PD voltage 308 is evaluated when the control signal is stable. This approach inherently filters out transient peaks and valleys, avoiding false interlock activations caused by the overshoot 318 (or undershoot) at modulation edges. Therefore, FIGS. 3A and 3B illustrate the robustness of the laser interlock system 102 using the ACSIA 120 to adapt to real-time control signals, overcome laser latency, and/or maintain interlock protection under dynamically changing modulation conditions.

As indicated above, FIGS. 3A and 3B are provided as an example. Other examples may differ from what is shown in and described with regard to FIGS. 3A and 3B.

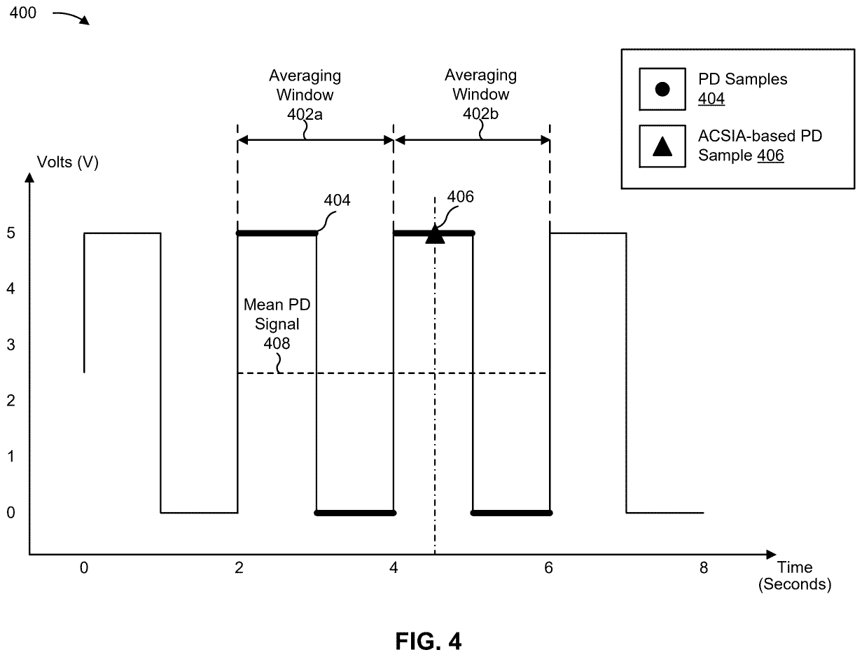

FIG. 4 shows a PD voltage sampling plot 400 according to a laser system operating according to the ACSIA 120 versus a cycle-wide averaging procedure. That is, the PD voltage sampling plot 400 illustrates the performance difference between a laser system using a cycle-wide averaging method and the laser interlock system 102 using an ACSIA 120.

As shown in FIG. 4, the PD voltage sampling plot 400 includes an averaging window 402a that spans from 2 to 4 seconds and an averaging window 402b that spans from 4 to 6 seconds. The averaging windows 402a and 402b may correspond to two consecutive windows that establish a duration used for a laser system to determine an average PD voltage value according to cycle-wide averaging. The multiple PD samples 404 spanning across the two consecutive windows may be individual PD voltage samples used to compute a mean PD signal 408 (e.g., an average voltage signal measured by the photodetector 110).

Conversely, as shown in FIG. 4, an ACSIA-based PD sample 406 is a single sample measured by photodetector 110 for the laser interlock system 102 that operates according to the ACSIA 120 (aligned with a verified control signal to verify steady-state).

In interlock systems that utilize cycle-wide averaging, laser output is evaluated solely through PD feedback. To differentiate between intentional modulation and abnormal laser behavior (e.g., fiber break or malfunction), these systems may implement a sliding time window to average PD voltage measurements. Accordingly, if the average PD signal within the averaging window 402b deviates from the average PD signal within the averaging window 402a (e.g., deviates by a voltage value satisfying a voltage threshold), then the laser system can interpret the change as a fault condition. Therefore, the cycle-wide averaging method introduces inherent latency that results from measuring across two consecutive windows. In slow or irregular modulation scenarios (such as a 0.5 Hz waveform with 1-second on-cycles and 1-second off-cycles, or in cases of 100-second on-cycles and 400-second off-cycles), each averaging window 402 may span a full modulation cycle to avoid false alarms. This results in delayed interlock response times (on the order of multiple seconds) which is unsuitable for protecting sensitive laser systems (e.g., laser systems that could be damaged from fluctuations in laser intensity output that last less than one second).

In contrast, the laser interlock system 102 that utilizes the ACSIA 120 offers a faster and more deterministic solution. For example, by evaluating the relevant steady-state portion of the signal, ACSIA 120 enables interlock response times comparable to response times of CW systems (e.g., less than 1 ms), regardless of modulation frequency. Additionally, unlike the averaging techniques of cycle-wide averaging (which rely on broad statistical smoothing), ACSIA 120 makes targeted, real-time decisions that minimize false positives while maintaining the speed and precision needed for both equipment protection and operator safety.

As indicated above, FIG. 4 is provided as an example. Other examples may differ from what is shown in and described with regard to FIG. 4.

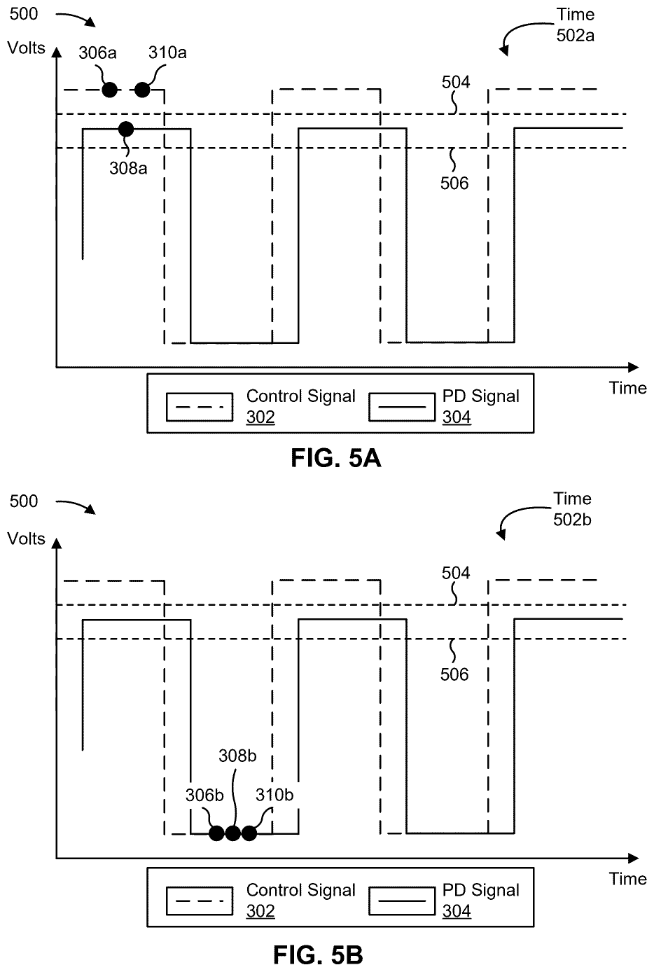

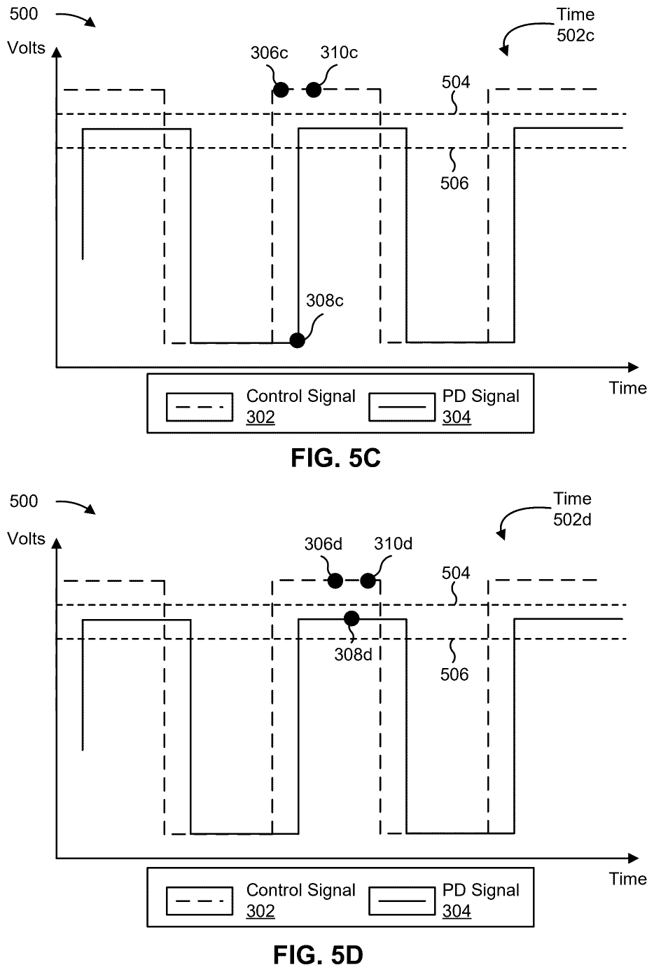

FIGS. 5A through 5D shows an example voltage sampling plot 500 over different points in time according to one or more implementations. For example, FIGS. 5A, 5B, 5C, and 5D respectively illustrate the laser interlock system 102 sampling voltage measurements (e.g., the CV1 306, the PD voltage 308, and the CV2 310) at a time 502a, a time 502b, a time 502c, and a time 502d. At time 502a, the laser interlock system 102 measures a CV1 306a, a PD voltage 308a, and a CV2 310a. At time 502b, the laser interlock system 102 measures a CV1 306b, a PD voltage 308b, and a CV2 310b. At time 502c, the laser interlock system 102 measures a CV1 306c, a PD voltage 308c, and a CV2 310c. At time 502d, the laser interlock system 102 measures a CV1 306d, a PD voltage 308d, and a CV2 310d. As shown in FIGS. 5A through 5D, the laser interlock system 102 may use the ACSIA 120 to determine whether to arm or disarm the interlock based on sampling the set of voltage measurements at a given time 502.

As shown in FIGS. 5A through 5D, the control signal 302 represents the control voltage provided to the laser 112 (e.g., via the control interface 106), which dictates the intensity of the laser output. Additionally, the PD signal 304 represents the PD voltage as measured by the photodetector 110 based on a light output obtained from the laser 112. Additionally, a line 504 represents the upper bound of the voltage range configured for the PD voltage and a line 506 represents the lower bound of the voltage range configured for the PD voltage (e.g., while the laser 112 is in the steady state). As described herein, the laser interlock system 102 may determine the upper and lower bonds of the voltage range based on measuring an initial PD voltage during the automatic threshold calculation mode (e.g., as described at reference number 210). Accordingly, the laser interlock system 102 may calculate the upper bound (e.g., line 504) as the product of the initial PD voltage and the upper percentage value stored at a register of the memory 116, and may calculate the lower bound (e.g., line 506) as the product of the initial PD voltage and the lower percentage value stored at a register of the memory 116.

In some implementations, the interlock mechanism of the laser interlock system 102 may be armed at a given time 502 if the measured values of CV1 306 and CV2 310 satisfy the steady-state conditions (e.g., satisfy the control signal threshold 312 and noise threshold 314, described herein) and the PD voltage 308 is within the upper and lower voltage safety bounds. Accordingly, as shown in FIGS. 5A and 5D, at the times 502a and 502d, the interlock mechanism is armed. Additionally, or alternatively, if the PD voltage 308 was measured outside the range defined by the upper and lower voltage safety bounds while the interlock mechanism is armed, then the laser interlock system 102 may trigger the relay 114 to shut down the laser 112 (e.g., as described herein).

The interlock mechanism of the laser interlock system 102 may be disarmed at a given time 502 if the measured values of CV1 306 and CV2 310 do not satisfy one or more of the steady-state conditions (e.g., do not satisfy at least one of the control signal threshold 312 or the noise threshold 314, described herein) or the PD voltage 308 is not within the upper and lower voltage safety bounds. Therefore, as shown by FIGS. 5B and 5C, at the times 502b and 502c, the interlock mechanism remains disarmed. By disarming the interlock mechanism when the conditions are not met, the laser interlock system 102 prevents false alarms and ensures safe operation of the laser 112.

As indicated above, FIG. 5 is provided as an example. Other examples may differ from what is shown in and described with regard to FIG. 5.

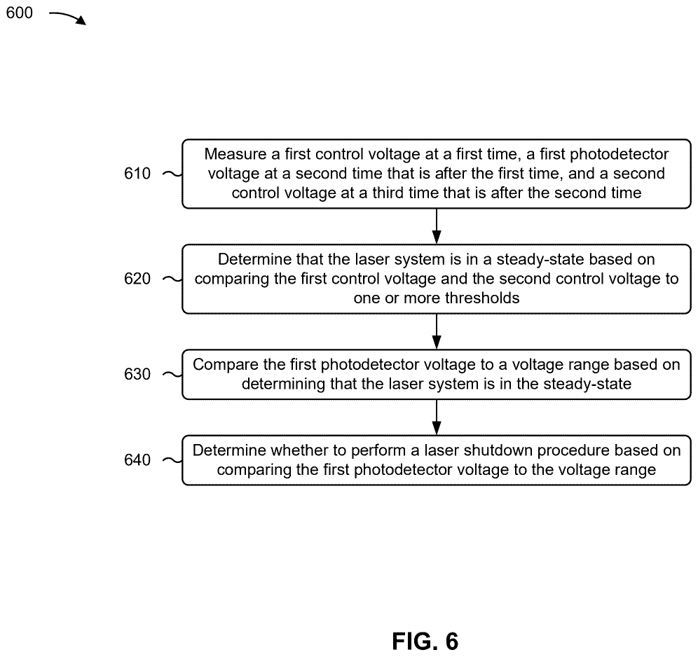

FIG. 6 is a flowchart of an example process 600 associated with embedded ACSIA for laser systems. One or more process blocks of FIG. 6 are performed by a laser system (e.g., the laser interlock system 102) and/or by another device or a group of devices separate from or including the laser system. Additionally, or alternatively, one or more process blocks of FIG. 6 may be performed by one or more components of laser interlock system 102, such as the bus 104, the control interface 106, the function generator 108, the photodetector 110, the laser 112, the relay 114, the memory 116, and/or the processor 118.

As shown in FIG. 6, process 600 includes measuring a first control voltage at a first time, a first photodetector voltage at a second time that is after the first time, and a second control voltage at a third time that is after the second time (block 610). For example, the laser system may measure a first control voltage at a first time, a first photodetector voltage at a second time that is after the first time, and a second control voltage at a third time that is after the second time, as described above.

As further shown in FIG. 6, process 600 includes determining that the laser system is in a steady-state based on comparing the first control voltage and the second control voltage to one or more thresholds (block 620). For example, the laser system may determine that the laser system is in a steady-state based on comparing the first control voltage and the second control voltage to one or more thresholds, as described above.

As further shown in FIG. 6, process 600 includes comparing the first photodetector voltage to a voltage range based on determining that the laser system is in the steady-state (block 630). For example, the laser system may compare the first photodetector voltage to a voltage range based on determining that the laser system is in the steady-state, as described above.

As further shown in FIG. 6, process 600 includes determining whether to perform a laser shutdown procedure based on comparing the first photodetector voltage to the voltage range (block 640). For example, the laser system may determine whether to perform a laser shutdown procedure based on comparing the first photodetector voltage to the voltage range, as described above.

Process 600 may include additional aspects, such as any single aspect or any combination of aspects described below and/or in connection with one or more other processes described elsewhere herein.

In a first aspect, the process 600 includes determining the voltage range comprises measuring a third control voltage at a fourth time, a second photodetector voltage at a fifth time that is after the fourth time, and a fourth control voltage at a sixth time that is after the fifth time, where the fourth time, the fifth time, and the sixth time are before the first time, determining that the laser system is in the steady-state based on comparing the third control voltage and the fourth control voltage to the one or more thresholds, reading, from one or more registers, a lower percentage value and an upper percentage value based on the laser system being in the steady-state, calculating a lower bound of the voltage range based on a product of the second photodetector voltage and the lower percentage value, and calculating an upper bound of the voltage range based on a product of the second photodetector voltage and the upper percentage value.

In a second aspect, alone or in combination with the first aspect, process 600 includes obtaining an external trigger indication, where determining the voltage range is based on the external trigger indication.

In a third aspect, alone or in combination with one or more of the first and second aspects, the laser system determines to perform the laser shutdown procedure based on the first photodetector voltage being outside of the voltage range, where (as part of laser shutdown procedure) process 600 includes opening a relay of the laser system, where a laser of the laser system turns off based on opening the relay, writing, to a register of the laser system, a voltage violation indication based on the first photodetector voltage being outside of the voltage range, and outputting an error code that indicates a shutdown of the laser based on the first photodetector voltage being outside of the voltage range.

In a fourth aspect, alone or in combination with one or more of the first through third aspects, the laser system determines to not perform the laser shutdown procedure based on the first photodetector voltage satisfying the voltage range, where process 600 includes maintaining an interlock procedure of the laser system based on the first photodetector voltage satisfying the voltage range.

In a fifth aspect, alone or in combination with one or more of the first through fourth aspects, the second time at which the first photodetector voltage is measured is a duration after the first time based on a configured delay.

In a sixth aspect, alone or in combination with one or more of the first through fifth aspects, process 600 includes comparing the first control voltage and the second control voltage to the one or more thresholds comprises comparing an absolute value of a difference between the first control voltage and the second control voltage to a voltage noise threshold from the one or more thresholds, and comparing the first control voltage to a control signal threshold, where determining that the laser system is in the steady-state is based on the absolute value of the difference between the first control voltage and the second control voltage being less than the voltage noise threshold and the first control voltage being greater than the control signal threshold.

In a seventh aspect, alone or in combination with one or more of the first through sixth aspects, the laser system operates in accordance with an ACSIA.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, the term “component” is intended to be broadly construed as hardware, firmware, and/or a combination of hardware and software. It will be apparent that systems and/or methods described herein may be implemented in different forms of hardware, firmware, or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be designed to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A method performed by a laser system, comprising:
measuring a first control voltage at a first time, a first photodetector voltage at a second time that is after the first time, and a second control voltage at a third time that is after the second time;
determining that the laser system is in a steady-state based on comparing the first control voltage and the second control voltage to one or more thresholds;
comparing the first photodetector voltage to a voltage range based on determining that the laser system is in the steady-state; and
determining whether to perform a laser shutdown procedure based on comparing the first photodetector voltage to the voltage range.

2. The method of claim 1, wherein determining the voltage range comprises:
measuring a third control voltage at a fourth time, a second photodetector voltage at a fifth time that is after the fourth time, and a fourth control voltage at a sixth time that is after the fifth time, wherein the fourth time, the fifth time, and the sixth time are before the first time;
determining that the laser system is in the steady-state based on comparing the third control voltage and the fourth control voltage to the one or more thresholds;
reading, from one or more registers, a lower percentage value and an upper percentage value based on the laser system being in the steady-state;
calculating a lower bound of the voltage range based on a product of the second photodetector voltage and the lower percentage value; and
calculating an upper bound of the voltage range based on a product of the second photodetector voltage and the upper percentage value.

3. The method of claim 2, further comprising:
obtaining an external trigger indication, wherein determining the voltage range is based on the external trigger indication.

4. The method of claim 1, wherein the laser system determines to perform the laser shutdown procedure based on the first photodetector voltage being outside of the voltage range, the laser shutdown procedure comprising:
opening a relay of the laser system, wherein a laser of the laser system turns off based on opening the relay;
writing, to a register of the laser system, a voltage violation indication based on the first photodetector voltage being outside of the voltage range; and
outputting an error code that indicates a shutdown of the laser based on the first photodetector voltage being outside of the voltage range.

5. The method of claim 1, wherein the laser system determines to not perform the laser shutdown procedure based on the first photodetector voltage satisfying the voltage range, the method further comprising:
maintaining an interlock procedure of the laser system based on the first photodetector voltage satisfying the voltage range.

6. The method of claim 1, wherein the second time at which the first photodetector voltage is measured is a duration after the first time based on a configured delay.

7. The method of claim 1, wherein comparing the first control voltage and the second control voltage to the one or more thresholds comprises:
comparing an absolute value of a difference between the first control voltage and the second control voltage to a voltage noise threshold from the one or more thresholds; and
comparing the first control voltage to a control signal threshold, wherein determining that the laser system is in the steady-state is based on the absolute value of the difference between the first control voltage and the second control voltage being less than the voltage noise threshold and the first control voltage being greater than the control signal threshold.

8. The method of claim 1, wherein the laser system operates in accordance with an adaptive control signal interlock algorithm (ACSIA).

9. A laser system, comprising:
one or more memories; and
one or more processors, coupled to the one or more memories, configured to cause the laser system to:
measure a first control voltage at a first time, a first photodetector voltage at a second time that is after the first time, and a second control voltage at a third time that is after the second time;
determine that the laser system is in a steady-state based on comparing the first control voltage and the second control voltage to one or more thresholds;
compare the first photodetector voltage to a voltage range based on determining that the laser system is in the steady-state; and
determine whether to perform a laser shutdown procedure based on comparing the first photodetector voltage to the voltage range.

10. The laser system of claim 9, wherein the one or more processors, to cause the laser system to determine the voltage range, are configured to cause the laser system to:
measure a third control voltage at a fourth time, a second photodetector voltage at a fifth time that is after the fourth time, and a fourth control voltage at a sixth time that is after the fifth time, wherein the fourth time, the fifth time, and the sixth time are before the first time;
determine that the laser system is in the steady-state based on comparing the third control voltage and the fourth control voltage to the one or more thresholds;
read, from one or more registers, a lower percentage value and an upper percentage value based on the laser system being in the steady-state;
calculate a lower bound of the voltage range based on a product of the second photodetector voltage and the lower percentage value; and
calculate an upper bound of the voltage range based on a product of the second photodetector voltage and the upper percentage value.

11. The laser system of claim 10, wherein the one or more processors are further configured to cause the laser system to:
obtain an external trigger indication, wherein determining the voltage range is based on the external trigger indication.

12. The laser system of claim 9, wherein the one or more processors cause the laser system to perform the laser shutdown procedure based on the first photodetector voltage being outside of the voltage range, and wherein to perform the laser shutdown procedure the one or more processors are further configured to cause the laser system to:
open a relay of the laser system, wherein a laser of the laser system turns off based on opening the relay;
write, to a register of the laser system, a voltage violation indication based on the first photodetector voltage being outside of the voltage range; and
output an error code that indicates a shutdown of the laser based on the first photodetector voltage being outside of the voltage range.

13. The laser system of claim 9, wherein the laser system determines to not perform the laser shutdown procedure based on the first photodetector voltage satisfying the voltage range, the one or more processors are further configured to cause the laser system to:
maintain an interlock procedure of the laser system based on the first photodetector voltage satisfying the voltage range.

14. The laser system of claim 9, wherein the second time at which the first photodetector voltage is measured is a duration after the first time based on a configured delay.

15. The laser system of claim 9, wherein the one or more processors, to cause the laser system to compare the first control voltage and the second control voltage to the one or more thresholds, are configured to cause the laser system to:
compare an absolute value of a difference between the first control voltage and the second control voltage to a voltage noise threshold from the one or more thresholds; and
compare the first control voltage to a control signal threshold, wherein determining that the laser system is in the steady-state is based on the absolute value of the difference between the first control voltage and the second control voltage being less than the voltage noise threshold and the first control voltage being greater than the control signal threshold.

16. The laser system of claim 9, wherein the laser system operates in accordance with an adaptive control signal interlock algorithm (ACSIA).

17. A laser interlock system, comprising:
a laser;
a function generator configured to generate a control signal;
a control interface configured to provide the control signal as input to the laser;
a photodetector configured to measure an output intensity from the laser;
a relay configured to disconnect the laser from a power source;
one or more memories storing one or more instructions of an adaptive control signal interlock algorithm (ACSIA); and
one or more processors, coupled to the one or more memories, wherein the one or more processors are configured to:
obtain, from the function generator, a first control voltage at a first time and a second control voltage at a third time;
obtain, from the photodetector, a first photodetector voltage at a second time, wherein the second time is after the first time and before the third time;
determine that the laser is in a steady-state based on comparing the first control voltage and the second control voltage to one or more thresholds;
compare the first photodetector voltage to a voltage range based on determining that the laser is in the steady-state; and
determine whether to trigger the relay to perform a laser shutdown procedure based on comparing the first photodetector voltage to the voltage range.

18. The laser interlock system of claim 17, wherein to determine the voltage range, the one or more processors are configured to:
obtain, from the function generator, a third control voltage at a fourth time and a fourth control voltage at a sixth time;
obtain, from the photodetector, a second photodetector voltage at a fifth time, wherein the fifth time is after the fourth time and before the fifth time, and wherein the fourth time, the fifth time, and the sixth time are before the first time;
determine that the laser is in the steady-state based on comparing the third control voltage and the fourth control voltage to the one or more thresholds;
read, from the one or more memories, a lower percentage value and an upper percentage value based on the laser being in the steady-state;
calculate a lower bound of the voltage range based on a product of the second photodetector voltage and the lower percentage value; and
calculate an upper bound of the voltage range based on a product of the second photodetector voltage and the upper percentage value.

19. The laser interlock system of claim 18, wherein the one or more processors are configured to:
obtain an external trigger indication, wherein determining the voltage range is based on the external trigger indication.

20. The laser interlock system of claim 17, wherein:
the one or more processors are configured to:
determine to perform the laser shutdown procedure based on the first photodetector voltage being outside of the voltage range;
output, to the relay, a trigger to open according to the laser shutdown procedure; and
the relay is configured to:
open in accordance with the trigger, wherein the laser turns off based on the relay opening.
